(19) United States
(12) Patent Application Publication
(10) Pub. No.: US 2026/0164732 A1
(43) Pub. Date: Jun. 11, 2026

(54) APPARATUS WITH BREAKDOWN VOLTAGE MANAGEMENT MECHANISM AND METHODS FOR OPERATING THE SAME

(71) Applicant: Micron Technology, Inc., Boise, ID (US)

(72) Inventor: Michael A. Smith, Boise, ID (US)

(21) Appl. No.: 19/355,889

(22) Filed: Oct. 10, 2025

Related U.S. Application Data
(60) Provisional application No. 63/729,061, filed on Dec. 6, 2024.

(51) Int. Cl. H10D 62/10; H10D 8/00; H10D 8/01

(52) U.S. Cl. CPC H10D 62/106; H10D 8/045; H10D 8/411; H10D 62/116; H10D 62/126

(57) ABSTRACT

Disclosed herein are methods, apparatuses and systems including breakdown voltage management mechanisms. In some embodiments, a semiconductor circuit includes one or more moat trenches disposed between a circuit component and a deep trench that separates adjacent circuit components.

### CROSS-REFERENCE TO RELATED APPLICATION(S)

The present application claims priority to U.S. Provisional Patent Application No. 63/729,061, filed Dec. 6, 2024, the disclosure of which is incorporated herein by reference in its entirety.

### TECHNICAL FIELD

The disclosed embodiments relate to devices, and, in particular, to semiconductor devices with breakdown voltage (BV) management mechanism and methods for operating the same.

### BACKGROUND

Semiconductor devices commonly employ high voltage (HV) circuits, such as for level shifters in NAND memory arrays. These circuits typically include specialized devices that operate at elevated voltages while maintaining electrical isolation between different voltage domains. Such HV circuits often utilize various management structures to control or manage the HV circuitry.

### BRIEF DESCRIPTION OF THE DRAWINGS

The foregoing and other objects, features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure.

FIG. 1 is a block diagram of a computing system in accordance with an embodiment of the present technology.

FIG. 2A is a cross-sectional view of a first semiconductor circuit in accordance with an embodiment of the present technology.

FIG. 2B is a detailed view of a portion of the first semiconductor circuit shown within dashed box 2B-2B of FIG. 2A in accordance with an embodiment of the present technology.

FIG. 3A is a cross-sectional view of a second semiconductor circuit in accordance with an embodiment of the present technology.

FIG. 3B is a detailed view of a portion of the second semiconductor circuit shown within dashed box 3B-3B of FIG. 3A in accordance with an embodiment of the present technology.

FIG. 4 is a flow diagram illustrating an example method of manufacturing an apparatus in accordance with an embodiment of the present technology.

FIG. 5 is a plan view of a semiconductor circuit having a first fin connection mechanism in accordance with an embodiment of the present technology.

FIG. 6 is a plan view of a semiconductor circuit having a second fin connection mechanism in accordance with an embodiment of the present technology.

FIG. 7 is a schematic view of a system that includes an apparatus in accordance with an embodiment of the present technology.

### DETAILED DESCRIPTION

As described in greater detail below, the technology disclosed herein relates to an apparatus, such as semiconductor devices, related methods, etc., for managing breakdown voltages, such as for HV circuits. Using HV circuits in NAND memory devices as an illustrative example, HV switches can be used for level shifting operations. Such HV switches can be configured to maintain output at specific voltage levels while supporting HV operations exceeding 10V, 20V, 30V, or more without breakdown or leakage. To accommodate such HV operating conditions, embodiments of the present technology can include moat trenches or shallow trench isolations (STIs) between local deep trenches (LDTs) and corresponding circuits/switches. For a given circuit (e.g., transistor) formed on a semiconductor substrate, the STI can be located between a terminal (e.g., drain) and an adjacent LDT. The STI can separate a doped region into a first doped region under the terminal and a fin portion that is located between the STI and the LDT. The STI can extend at least to a dopant depth of the doped region. The STI can effectively form a moat with the fin portion and at least partially surround the functional circuit (e.g., HV switch/transistor).

The STIs can each have a targeted shape configured to prevent introduction of implants (e.g., 23-level implant) into the STI during existing manufacturing process steps. For example, in some embodiments, the manufacturing process can be adjusted to implant a first material, such as the 23-level implant before an etching step. The subsequent etching step can remove the first implant material from an initial trench and transform the initial trench to the STI. Afterwards, lining material can be deposited over the substrate and into the finalized STI to protect the sidewalls of the LDT during the subsequent second material implant (e.g., the 2 T/Boron implant). Here, the finalized STI can have an opening width, a sidewall slope, a STI depth, or a combination thereof that causes the deposited lining material to pinch off and fully cover a thalweg (e.g., the bottom/lowest portion of the STI). In other words, opposing sides of the sloped sidewalls of the STI can be configured such that the lining material deposited thereon will connect/merge and form a thicker cover over the thalweg. Accordingly, the lining portion can prevent or drastically reduce the second material from entering below the thalweg and into the corresponding portion of the substrate.

In some embodiments, multiple STIs can be formed between the LDT and the functional circuit. The multiple STIs can have a common depth in one or more embodiments. In other embodiments, the multiple STIs can have a different depth, such as to control or reduce an angle of a nearest path connecting the first doped region of the functional circuit and the LDT. The one or more STIs can effectively increase the length and/or shape of such path between the LDT (e.g., the implant region, such as the 2 T or Boron implant under the LDT) and the first doped region of the corresponding/adjacent circuit. Accordingly, by increasing the path distance and/or controlling the shape of the path, the STIs can increase the BV performance/rating of the overall device.

### Example Environment

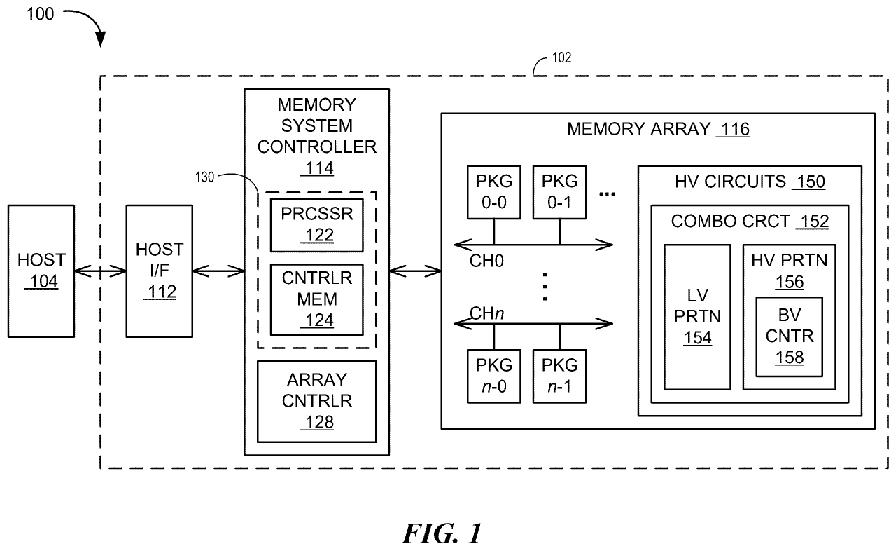

FIG. 1 is a block diagram of a computing system 100 in accordance with an embodiment of the present technology. The computing system 100 can include a personal computing device/system, an enterprise system, a mobile device, a server system, a database system, a distributed computing system, a vehicle management/control system, or the like.

The computing system 100 can have a memory system 102 coupled to a host device 104. The host device 104 can include one or more system processors that can write data to and/or read data from the memory system 102. For example, the host device 104 can include an upstream central processing unit (CPU). Also, for example, the host device 104 can be configured to control operation of a corresponding structure or system, such as other components (not shown) of the computing system 100 or structures operably coupled to the computing system.

The memory system 102 can include circuitry configured to store data (via, e.g., write operations) and provide access to stored data (via, e.g., read operations). For example, the memory system 102 can include a persistent or non-volatile data storage system, such as a NAND-based Flash drive system, an SSD system, an SD card, or the like. In some embodiments, the memory system 102 can correspond to a Universal Flash Storage (UFS) device.

The memory system 102 can include a host interface 112 (e.g., buffers, transmitters, receivers, and/or the like) configured to facilitate communications with the host device 104. The host interface 112 can be configured to support one or more host interconnect schemes, such as Universal Serial Bus (USB), Peripheral Component Interconnect (PCI), Serial AT Attachment (SATA), or the like. The host interface 112 can receive commands, addresses, data (e.g., write data), and/or other information from the host device 104. The host interface 112 can also send data (e.g., read data) and/or other information to the host device 104. In some embodiments, the host interface 112 can be configured to implement the UFS protocols in communicating with the host device 104.

The memory system 102 can further include a memory system controller 114 (also called a micro controller) and a memory array 116. The memory array 116 can include memory cells that are configured to store a unit of information. The memory system controller 114 can be configured to control the overall operation of the memory system 102, including the operations of the memory array 116.

In some embodiments, the memory array 116 can include a set of data storage devices (e.g., NAND Flash devices), packages, dies, or the like. Each of the packages can include a set of memory cells that each store data in a charge storage structure. The memory cells can include, for example, floating gate, charge trap, phase change, ferroelectric, magnetoresitive, and/or other suitable storage elements configured to store data persistently or semi-persistently. The memory cells can be one-transistor memory cells that can be programmed to a target state to represent information. For instance, electric charge can be placed on, or removed from, the charge storage structure (e.g., the charge trap or the floating gate) of the memory cell to program the cell to a particular data state. The stored charge on the charge storage structure of the memory cell can indicate the Vt of the cell. For example, a single level cell (SLC) can be programmed to a targeted one of two different data states, which can be represented by the binary units 1 or 0. Also, some flash memory cells can be programmed to a targeted one of more than two data states. Multilevel cells (MLCs) may be programmed to any one of four data states (e.g., represented by the binary 00, 01, 10, 11) to store two bits of data. Similarly, triple level cells (TLCs) may be programmed to one of eight (i.e., 2³) data states to store three bits of data, and quad level cells (QLCs) may be programmed to one of 16 (i.e., 2⁴) data states to store four bits of data.

Such memory cells may be arranged in rows (e.g., each corresponding to a word line 143) and columns (e.g., each corresponding to a bit line). The arrangements can further correspond to different groupings for the memory cells. For example, each word line can correspond to one or more memory pages. Also, the memory array 116 can include memory blocks that each include a set of memory pages. In operation, the data can be written or otherwise programmed (e.g., erased) with regards to the various memory regions of the memory array 116, such as by writing to groups of pages and/or memory blocks. In NAND-based memory, a write operation often includes programming the memory cells in selected memory pages with specific data values (e.g., a string of data bits having a value of either logic 0 or logic 1). An erase operation is similar to a write operation, except that the erase operation re-programs an entire memory block or multiple memory blocks to the same data state (e.g., logic 0).

While the memory array 116 is described with respect to the memory cells, it is understood that the memory array 116 can include other components (not shown). For example, the memory array 116 can also include other circuit components, such as multiplexers, decoders, buffers, read/write drivers, address registers, data out/data in registers, etc., for accessing and/or programming (e.g., writing) the data and for other functionalities.

As described above, the memory system controller 114 can be configured to control the operations of the memory array 116. The memory system controller 114 can include a processor 122, such as a special purpose logic circuitry (e.g., a field programmable gate array (FPGA), an application specific integrated circuit (ASIC), etc.), a microprocessor, or other suitable processor. The processor 122 can execute instructions encoded in hardware, firmware, and/or software (e.g., instructions stored in controller embedded memory 124 to execute various processes, logic flows, and routines for controlling operation of the memory system 102 and/or the memory array 116.

Further, the memory system controller 114 can further include an array controller 128 that controls or oversees detailed or targeted aspects of operating the memory array 116. For example, the array controller 128 can provide a communication interface between the processor 122 and the memory array 116 (e.g., the components therein). The array controller 128 can function as a multiplexer/demultiplexer, such as for handling transport of data along serial connection to flash devices in the memory array 116.

In controlling the operations of the memory system 102, the memory system controller 114 (via, e.g., the processor 122, the embedded memory 124, and/or the array controller 128) can implement a Flash Translation Layer (FTL) 130. The FTL 130 can include a set of functions or operations that provide translations for the memory array 116 (e.g., the Flash devices therein). For example, the FTL 130 can include the logical-physical address translation, such as by providing the mapping between virtual or logical addresses used by the operating system to the corresponding physical addresses that identify the Flash device and the location therein (e.g., the layer, the page, the block, the row, the column, etc.). Also, the FTL 130 can include a garbage collection function that extracts useful data from partially filed units (e.g., memory blocks) and combines them to a smaller set of memory units. The FTL 130 can include other functions, such as wear-leveling, bad block management, concurrency (e.g., handling concurrent events), page allocation, error correction code (e.g., error recovery), or the like.

The memory array 116 can include HV circuits 150 (e.g., HV transistors/switches) that operate with voltages exceeding a relatively high level (e.g., 5V, 10V, 15V, 20V, 30V, or greater). For example, the HV circuits 150 can be included in level shifters within NAND memory devices. In some embodiments, the HV circuits 150 can be configured to control or maintain the output of the switch to a targeted level (e.g., Vlow of 0V/ground, Vneg of less than 0V for block select switches, etc.). Additionally or alternatively, the HV circuits 150 can be configured to assist the output to rise above Vlow and then support a HV output (e.g., greater than 20V or 30V) without leaking or breakdown.

In some embodiments, the HV circuits 150 can have an asymmetric configuration (e.g., in the physical/silicon-level layout) that utilizes local deep trench process to control dimensions relating to isolation and BV. Accordingly, the HV circuits 150 can include a combination circuitry 152 that has a low voltage (LV) portion 154 and a HV portion 156. The HV portion 156 can operate according to the HV levels, and the LV portion 154 can operate according to lower voltage levels. To accommodate the different operating voltages, the HV portion 156 can have a larger footprint than the LV portion 154, thereby causing the asymmetry in the combination circuit 152.

The combination circuit 152 (e.g., at the HV portion 156) can include one or more BV control structures 158, such as LDT, STI, fin, or a combination thereof. Details regarding the BV control structures 158 are described below.

### Example Circuit Features

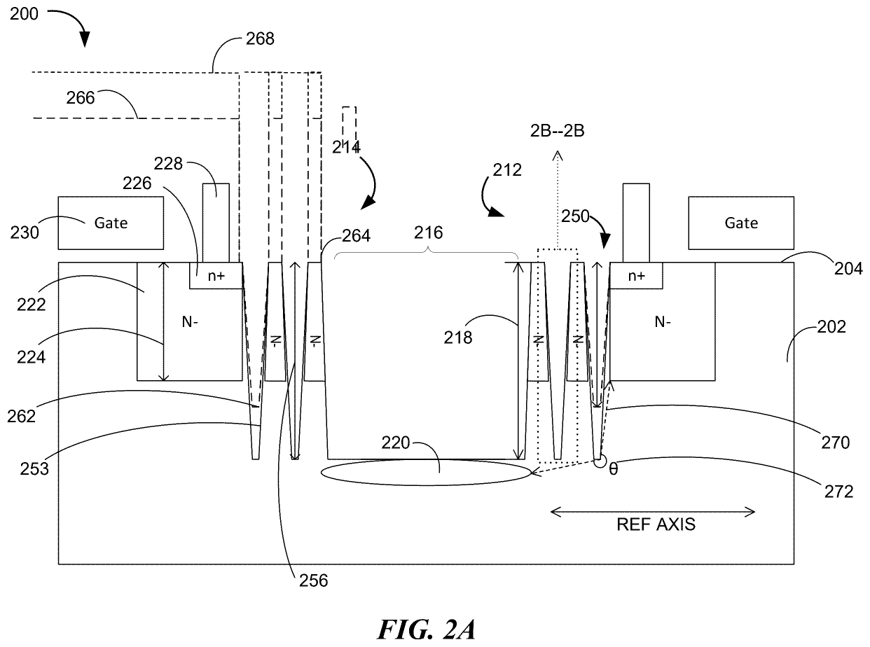

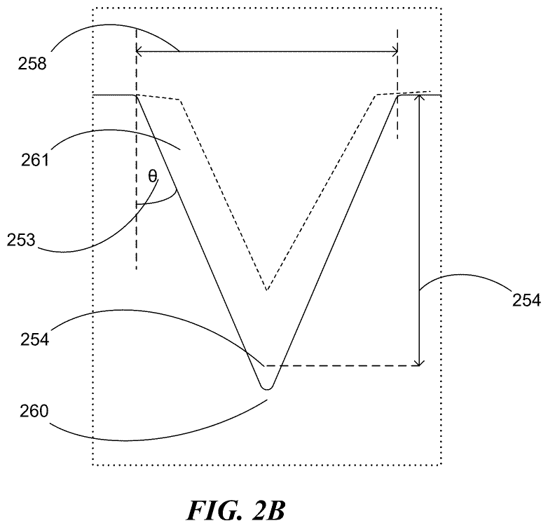

FIG. 2A is a cross-sectional view of a first semiconductor circuit 200, and FIG. 2B is a detailed view of a portion of the first semiconductor circuit 200, both in accordance with an embodiment of the present technology. Referring to FIG. 2A and FIG. 2B together, the first semiconductor circuit 200 can represent an instance of the HV circuit 150 of FIG. 1, a combination circuit 152 of FIG. 1, the HV portion 156 of FIG. 1, the BV control structures 158 of FIG. 1, a portion thereof, or a combination thereof. For illustrative purposes, the first semiconductor circuit 200 is described using a deep N-well or a triple well design. However, it is understood that the first semiconductor circuit 200 can be a different design, such as a Pwell design.

The first semiconductor circuit 200 can include a semiconductor substrate 202 having a first circuit 212 and a second circuit 214 formed on a substrate top surface 204. The first circuit 212 and the second circuit 214 can include switches or transistors, including the HV circuits 150. The adjacent first circuit 212 and the second circuit 214 can be separated by a LDT 216 that extend below the substrate top surface 204 by a deep trench depth 218.

The LDT 216 can correspond to a depression configured to function as isolation structure formed in the semiconductor substrate 202. Accordingly, the LDT 216 can be used to separate circuit elements, particularly in high-voltage applications. The LDT 216 can include an implanted floor region 220 that corresponds to a portion of the substrate 202 under the floor of the LDT 216 and containing a type of implants (e.g., 2 T implants, such as Boron). The LDT 216, along with the implanted floor region 220, can function as an isolation mechanism between the LV portion 154 of FIG. 1 and the HV portion 156. In other words, the LDT 216 and the implanted floor region 220 can correspond to instances of the BV control structures 158.

The LDT 216 can separate doped regions of the adjacent devices, such as first doped regions 222 of the first circuit 212 and the second circuit 214. For the illustrated N-well example, the first doped regions 222 can correspond to the N-regions located on terminal portions of the first circuit 212 and the second circuit 214. The first doped regions 222 can extend below the substrate top surface 204 by a dopant depth 224. Also for the illustrated N-well example, the first circuit 212 and the second circuit 214 can each include a second doped region 226 (e.g., N+ region) embedded in the first doped region 222. The second doped region 226 can have a complementary doping type to the first doped region 222 and have a shallower depth. Each of the first circuit 212 and the second circuit 214 can have a terminal 228 (e.g., a metal connector) contacting the second doped region 226 and extending above the substrate top surface 204. Moreover, each of the first circuit 212 and the second circuit 214 can have a matching/mirroring structure (e.g., another combination of the N-region, N+ region, and a terminal; not shown) opposite an undoped substrate portion, with a gate 230 over the undoped substrate portion. Accordingly, when a voltage level is applied to the gate 230, the corresponding circuit 212/214 can be activated, and current can flow between the opposing terminals and across the N+ doped regions, N-doped regions, and the undoped substrate portion between the opposing terminals. The current can flow parallel to the reference axis, and the arrangement of the circuits 212 and 214 and the LDT 216 can also be parallel to the reference axis.

In addition to the LDT 216, the first semiconductor circuit 200 can have one or more moat trenches 250 located between the first regions 226 and the LDT 216. Each of the moat trenches 250 can correspond to depressions that extend below the substrate top surface 204 by a moat-trench depth 256. The moat trenches 250 can have sidewalls 252 that are sloped to extend downward and toward each other (e.g., according to a ‘V’ shape). The sloped sidewalls 252 can be formed to have a sidewall slope 253 that is measured at a junction between the sloped sidewalls 252 and the substrate top surface 204. The sidewall slope 253 can represent an angle measured relative to the substrate top surface (e.g., a lateral/horizontal direction). Opposing instances of the sloped sidewalls 252 can extend downward and toward each other, thereby forming a bottom portion or a valley thalweg 254 of the moat trench 250. The valley thalweg 254 can correspond to the lowest point of the depression, which can be configured to be at the Moat trench depth 256. The Moat trenches 250 can each have a trench opening width 258 that is measure across the opposing sidewalls 252 and at the height of the substrate top surface 204. Based on the sidewall slope 253, the trench opening width 258 can correspond to the widest separation between the opposing sidewalls 252.

The Moat trenches 250 having the sloped sidewalls 252 according to the sidewall slope, the trench opening width 258, and/or the STI trench depth can correspond go instances of the BV control structures 158. The Moat trenches 250 can have the Moat trench depth 256 that is equal to or greater than the dopant depth 224. Accordingly, the Moat trenches 250 separate one or more fin portions 264 away from the corresponding circuits. For example, the Moat trenches 250 can separate the doped region into the one or more fins and the first doped region 222 of the first circuit 212. Thus, the Moat trenches 250 between the first doped region 222 and the LDT 216 increase a distance in the path between the implant region 220 under the LDT 216 and the first doped region 222 and the corresponding circuit (e.g., the first circuit 212). The increased distance improves the BV performance for the corresponding circuits. The fin portions 264 can have the same dopant type as the first doped region 222 (e.g., resulting from forming the moat trench within a commonly doped region), remain undoped and matching the well or the remainder of the substrate 202.

The circuit 200 can include one or multiple Moat trenches 250 between a switch and an adjacent LDT 216. In some embodiments, the multiple Moat trenches 250 between the corresponding pair of switch and LDT can have common Moat trench depth 256 that extends past the dopant depth 224 and up to or equal to the deep trench depth 218. In other embodiments, the multiple Moat trenches 250 between the corresponding pair of switch and LDT can have different and controlled Moat trench depth 256, so as to provide a shaped envelop or outline for the Moat trenches 250 (e.g., for the corresponding valley thalwegs 254). For example, the STI closest to the first doped region 222 can have the shallowest depth, and STIs closer to the LDT can have successively deeper depths. Accordingly, the controlled trench depths can provide a specific separation distance 270 and a path arc 272 for a shortest path through the substrate 202 between the first doped region 222 and the implant region 220.

Additionally, to increase the BV performance, the Moat trenches 250 can have one or more physical configurations that prevent dopants from entering below the Moat trenches 250 (e.g., below or through the valley thalweg 254). For example, the Moat trenches 250 can have the sidewall slope 253, the trench opening, the Moat trench depth 256, or a combination thereof that provides an undoped trench-bottom 260 (e.g., a portion of the substrate 202 directly under the valley thalweg 254 of the Moat trenches 250) across one or more implantation processes. In some embodiments, the sidewall slope 253, the trench opening, the Moat trench depth 256, or a combination thereof can be configured to cause an implant control layer 261 (e.g., an oxide layer deposited before an implanting process, such as 2 T, to protect the sidewalls) formed on opposing sloped sidewalls 252 to contact, thereby pinching off the valley bottom. The implant control layer 261 can form a thicker (in comparison to the thickness over the sidewalls) cover over the valley thalweg 254, thereby preventing the implant to enter into the valley bottom. Some examples of the physical configuration may include the Moat trench depth 256 greater than 0.5 um, the sidewall slope 253 of 91 degrees to 95 degrees from the substrate top surface 204, and/or the trench opening width 258 of 0.01 um to 0.1 um. The corresponding thickness of the implant control layer 261 over the valley thalweg 254 can be 0.01 um or thicker.

Similar to the implant control layer 261, the manufacturing method for the circuit 200 can utilize one or more masks, such as for etching (e.g., in forming the Moat trenches 250, the LDT 216, and/or the like) and/or doping and implantation. For example, the manufacturing method can utilize a first mask 266 for initially etching, forming the implant control layer 261, depositing 23-layer implantation, or a combination thereof. The manufacturing method can further utilize a second mask 268 for additional etching, such as to deepen or finalize the trenches. In some embodiments, the manufacturing method can implement the additional etching after the layer-23 implantation process, thereby finalizing/deepening the Moat trenches 250 past the implanted portion through the second mask 268. Accordingly, the Moat trenches 250 can be formed above the undoped trench-bottom 260. The method can include forming the implant control layer 261 after the deepening/finalizing process and/or using the second mask 268. The method can subsequently include depositing a second implant material (e.g., 2 T/Boron), such as to form the implant region 220 under the finalized LDT 216. The implant control layer 261 can prevent the second implant material from entering the undoped trench-bottom 260 as described above. Additional details regarding the manufacturing method are described below.

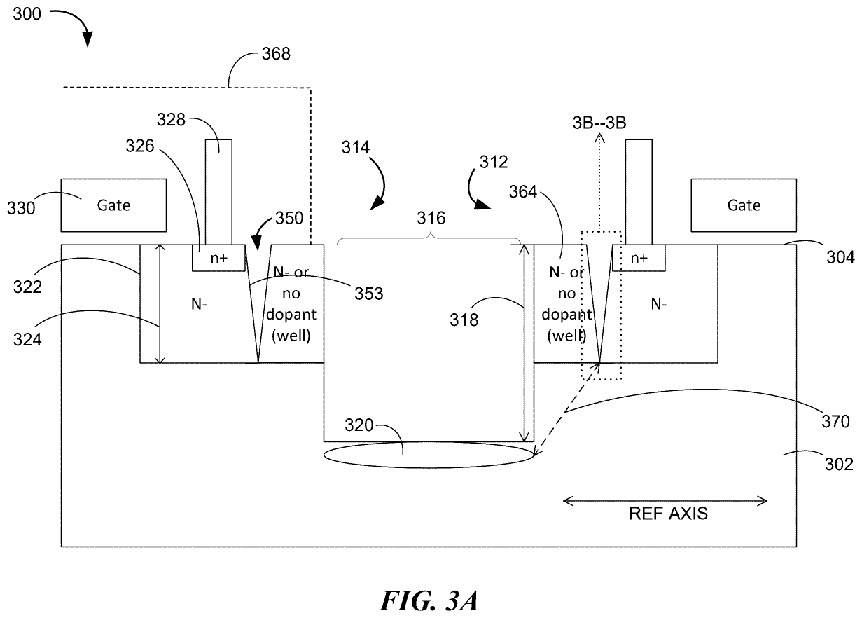

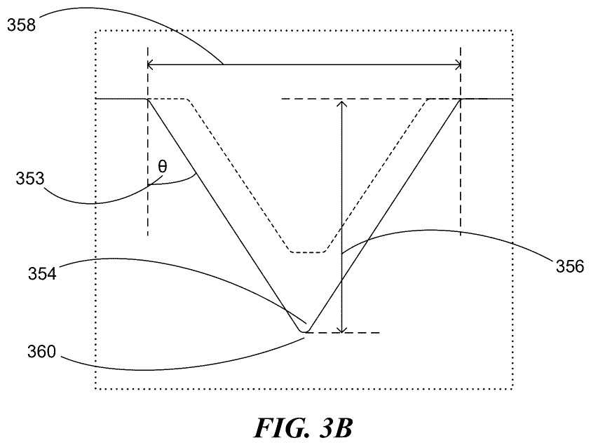

FIG. 3A is a cross-sectional view of a second semiconductor circuit 300, and FIG. 3B is a detailed view of a portion of the second semiconductor circuit 300, both in accordance with an embodiment of the present technology. Referring to FIG. 3A and FIG. 3B together, the second semiconductor circuit 300 can represent an instance of the HV circuit 150 of FIG. 1, a combination circuit 152 of FIG. 1, the HV portion 156 of FIG. 1, the BV control structures 158 of FIG. 1, a portion thereof, or a combination thereof. For illustrative purposes, the first semiconductor circuit 300 is described using a deep N-well or a triple well design. However, it is understood that the first semiconductor circuit 300 can be a different design, such as a Pwell design.

The second semiconductor circuit 300 can be similar to the first semiconductor circuit 200. For example, the second semiconductor circuit 300 can include a first circuit 312 and a second circuit 314 (e.g., transistors, switches, etc.) separated by a local deep trench (LDT) 316 having a deep trench depth 318. The LDT 316 can have an implant region 320 (e.g., 23-level implant, 2 T implant, Boron, etc.) below a floor of the LDT 316. The LDT 316 with the implant region 320 can be configured to isolate the adjacent/abutting first circuit 312 and the second circuit 314. Each of the first circuit 312 and the second circuit 314 can include a first doped region 322 (e.g., N−) having a dopant depth 324 and a second doped region 326 (e.g., N+) having a different/complementary dopant on or embedded within the first doped region 322. The first circuit 312 and the second circuit 314 can each have a terminal 328, such as a drain, over or directly on the second doped region 326. Each of the first circuit 312 and the second circuit 314 can have a mirroring structure (e.g., a combination of the first doped region 322, the second doped region 326, and the terminal 328) opposite the first structure and separated by a current channel portion. The first circuit 312 and the second circuit 314 can each have a gate 330 over the current channel portion. The first circuit 312 and the second circuit 314 can be operated by applying a voltage to the corresponding gate 330, thereby allowing a current to flow across the current channel portion along a direction parallel to a reference axis and through the terminals 328 for the circuit.

The second semiconductor circuit 300 can include one or more moat trenches (e.g., STIs) 350 between and separating fin portions 364 from the first doped region 322. The moat trenches 350 can include sloped sidewalls 352 that extend downward from a substrate top surface 304 and toward opposing instances of each other according to a sidewall slope 353 to form a valley thalweg 354 at a moat trench depth 356. The moat trench depth 356 can be equal to or deeper than the dopant depth 324. Different from the first semiconductor circuit 200, the moat trenches 350 can have the moat trench depth 356 and shallower than the deep trench depth 318; accordingly, the moat trenches 350 can include STIs.

In some embodiments, the moat trenches 350 can have the physical configuration, such as the sloped sidewalls 352, the sidewall slope 353, the moat trench depth 356, and/or a trench opening width 358. For example, the physical configuration can allow the implant control layer to form a thicker cover over the valley thalweg 354 than over the sidewalls. The thicker coverage can prevent dopants/implants to enter through the valley thalweg 354, thereby preserving an undoped trench-bottom at or below the valley thalweg 354. Thus, the moat trenches 350 can increase a separation distance 370 between the first doped region 322 along a path between the first doped region 322 and the next implant region (e.g., the implant region 320). The increased separation distance 370 can further improve the BV performance of the second semiconductor circuit 300.

In manufacturing the second semiconductor circuit 300, the LDT 316 can be finalized at the same time as the moat trenches 350 after a first implanting process (e.g., 23 level implant). Accordingly, any implants that may have entered under an initial trench can be removed during the finalization process, and the subsequently formed implant control layer can prevent a second implant (e.g., 2 T implant) from entering through the bottom of the moat trenches 350. In other embodiments, the moat trenches 350 can be formed/finalized at the initial trenching process. The first and second implanting process can occur after a mask/filler 368 is formed over the STIs, thereby preventing the implants from entering the floor of the moat trenches 350. The mask/filler can be removed with the implant control layer.

### Manufacturing Flow

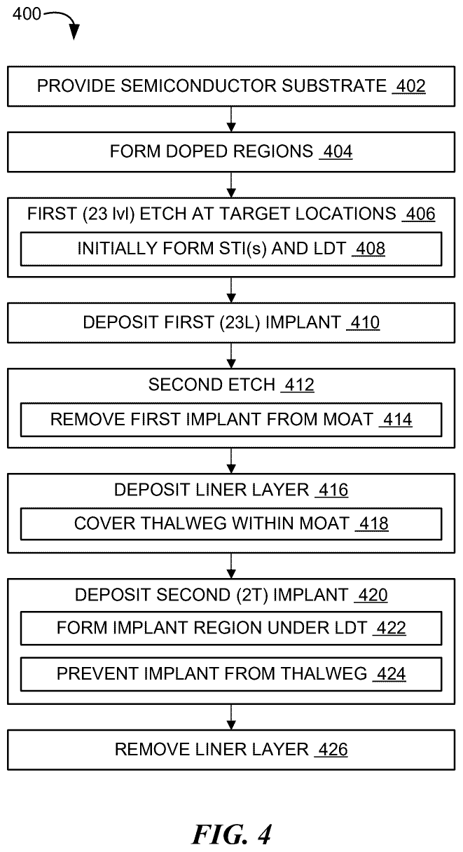

FIG. 4 is a flow diagram illustrating an example method 400 of manufacturing an apparatus (e.g., the circuit 200 of FIG. 2A/2B, the circuit 300 of FIG. 3A/3B, or both) in accordance with an embodiment of the present technology. The method 400 can be for implementing/forming the one or more BV control structures 158 of FIG. 1 in semiconductor circuitry, such as for HV switches/transistors.

The method 400 can include providing a semiconductor substrate (e.g., substrate 202/302) at block 402 followed by forming doped regions as shown at block 404. The doped regions can include the first doped regions 222/322 and/or the second doped regions 226/326 for forming the circuit components (e.g., the first and second circuits 212/214 and 312/314). For deep N-well circuits, the first doped regions can include N-and the second doped regions can include N+.

The method 400 can include performing a first etch at target locations as shown at block 406. The first etching process can initially form shallower trenches that can be later finalized to the LDTs 218/318, the moat trenches 250/350, or a combination thereof as shown at block 408. The etching process can include forming/patterning the first processing mask 266. In some embodiments, the etching can correspond to a 23 level masking/etching process.

At block 410, the method 400 can include depositing a first implant over the substrate. The first implant can correspond to 23 level implant (e.g., Boron). In some embodiments, the first implant can be introduced into the initially formed shallower trenches. In other embodiments, the moat trenches 350 (e.g., STIs) can be masked or covered, thereby preventing the first implants from entering into the moat trenches 350.

At block 412, the method 400 can include a second etch configured to deepen/finalize one or more of the initially formed shallower trenches. For example, the second etch can finalize the LDTs 216/316 and/or the moat trenches 250/350. The second etch can form the LDTs having the deep trench depth 218/318, the most trenches having the moat trench depth 256/356, or a combination thereof.

In implementing the second etch, the method 400 can include removing first implant from within the moat trenches as shown at block 414. For example, when the initial moat trenches are uncovered and have first implants at the floor, the second etch can remove the portions having the first implant in deepening the trenches. As a result, the second etch can produce the moat trenches having the undoped trench-bottoms 260/360.

In some embodiments, at block 416, the method 400 can include depositing a lining layer, such as the implant control layer 261 of FIG. 2B, in preparation for a subsequent/second implantation. For example, the method 400 can include forming an oxide layer over the substrate, including within the moat trenches. As described above, based on the physical configurations of the moat trenches, depositing the lining layer can correspond to forming a thicker coverage over the thalweg within the moat trenches as shown on block 418.

At block 420, the method 400 can include depositing a second implant, such as 2 T implants (e.g., Boron). Depositing the second implant can correspond to forming the implant region 220/320 under the LDT as shown in block 422. Similarly, as shown in block 424, the lining layer can prevent the second implant from reaching the thalweg within the moat trenches. At block 426, the lining layer can be removed after the implantation.

### Example Fin Connections

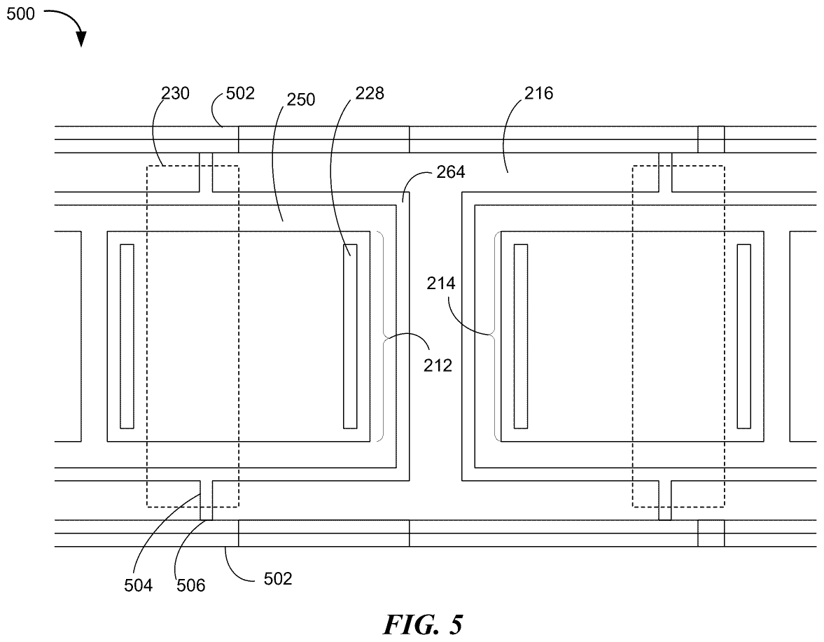

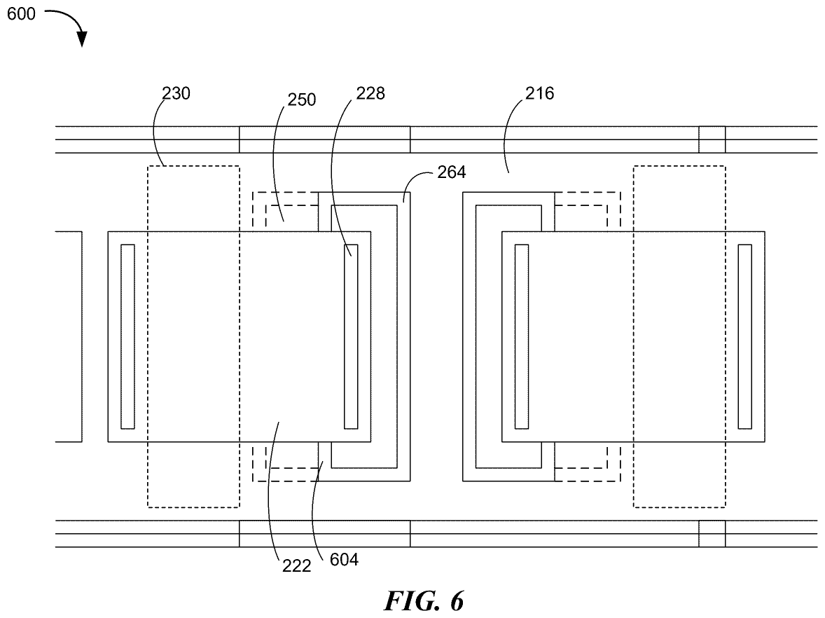

FIG. 5 is a plan view of a semiconductor circuit (e.g., the circuit 200 of FIG. 2A/2B) having a first fin connection mechanism 500 in accordance with an embodiment of the present technology. FIG. 6 is a plan view of a semiconductor circuit (e.g., the circuit 200) having a second fin connection mechanism 600 in accordance with an embodiment of the present technology. FIG. 5 and FIG. 6 illustrate different connection configurations for the fin portions resulting from the moat trenches. For illustrative purposes, FIG. 5 and FIG. 6 use the circuit (e.g., circuit 200 of FIG. 2A/2B) having the deeper moat trenches 250 of FIG. 2A/2B. However, it is understood that the fin connection configurations of FIG. 5 and FIG. 6 can apply to other circuits (e.g., circuit 300 of FIG. 3A/3B having STIs 350).

The circuit 200 can have the moat trench 250 between the first circuit 212 and the fin portion 264. The moat trench 250 can encircle a perimeter of the first circuit 212. The LDT 216 can at least partially surround the first circuit 212 outside of the fin portion 264. In other words, the fin portion 264 can be located between the moat trench 250 and the LDT 216. The LDT can separate the fin portion from another fin portion surrounding an adjacent circuit (e.g., the second circuit 214). In some embodiments, the moat trench 250 and the fin portion 264 can surround a pair of HV and LV switches, and the LDT can separate an adjacent pair of HV switches.

The circuit components (e.g., switches) can be arranged linearly along a direction parallel to the reference direction (e.g., the direction of current flow). The circuit 200 can further include guard regions 502 that extend parallel to the reference direction and on opposite sides of the circuit components. The guard regions 502 can correspond to mesas in the semiconductor substrate 202 of FIG. 2A that separate the circuit components from other circuitry formed on the same substrate. In some embodiments, the guard regions 502 can have the same charge type as the well (e.g., P for the circuit 200) or the remainder/non-doped portions of the substrate.

For the first fin connection mechanism 500 of FIG. 5, the fin portion 264 (e.g., each of the rings) can have a connection portion 504 that extend toward and connect with one of the guard regions 502. Accordingly, when the fin portion 264 has the same dopant type (e.g., N−) as the first doped region 222 of FIG. 2A, the connection portion 504 and the corresponding connected portion of the guard region 502 can form a controlled junction 506 having complementary dopants on opposing sides. In other words, the controlled junction 506 can include a P-N junction/diode. In some embodiments, the controlled junction can be located under/overlapped by the gate 230.

For the second fin connection mechanism 600 of FIG. 6, the fin portion 264 can have a connection portion 604 that extends towards and connects to the first doped region 222. Accordingly, when the fin portion 264 remains undoped and matching the undoped state of the substrate, the junction can form the P-N junction/diode. Alternatively, the fin portion 264 can have the matching dopant as the first doped region 222. In some embodiments, the junction can be closer to the terminal 228. In other embodiments, the junction can be closer to the gate 230.

### Overall System

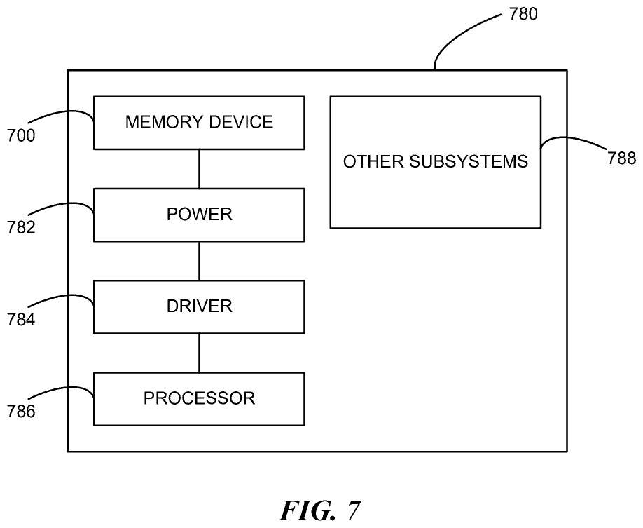

FIG. 7 is a schematic view of a system that includes an apparatus in accordance with embodiments of the present technology. Any one of the foregoing apparatuses (e.g., memory devices) described above with reference to FIGS. 1-4 can be incorporated into any of a myriad of larger and/or more complex systems, a representative example of which is system 780 shown schematically in FIG. 7. The system 780 can include a memory device 700, a power source 782, a driver 784, a processor 786, and/or other subsystems or components 788. The memory device 700 can include features generally similar to those of the apparatus described above with reference to one or more of the FIGS, and can therefore include various features for performing a direct read request from a host device. The resulting system 780 can perform any of a wide variety of functions, such as memory storage, data processing, and/or other suitable functions. Accordingly, representative systems 780 can include, without limitation, hand-held devices (e.g., mobile phones, tablets, digital readers, and digital audio players), computers, vehicles, appliances and other products. Components of the system 780 may be housed in a single unit or distributed over multiple, interconnected units (e.g., through a communications network). The components of the system 780 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of NAND Flash devices. Apparatuses configured in accordance with other embodiments of the present technology, however, can include other types of suitable storage media in addition to or in lieu of NAND Flash devices, such as, devices incorporating NOR-based non-volatile storage media (e.g., NAND flash), magnetic storage media, phase-change storage media, ferroelectric storage media, dynamic random access memory (DRAM) devices, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term “dynamic” as used herein describes processes, functions, actions or implementation occurring during operation, usage, or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to one or more of the FIGS. described above.

I/We claim:

1. A semiconductor device, comprising:
a semiconductor substrate;
a first circuit formed on the semiconductor substrate, the first circuit having a first circuit terminal;
a second circuit formed on the semiconductor substrate, the second circuit having a second circuit terminal adjacent to the first circuit terminal;
a local deep trench (LDT) formed in the semiconductor substrate and between the first and second circuit terminals, wherein the LDT separates the first circuit from the second circuit;
a fin portion between the LDT and the first circuit; and
a shallow trench isolation (STI) between the fin portion and the second circuit terminal, wherein the STI includes a depression in the substrate separating the second circuit from the fin portion.

2. The semiconductor device of claim 1, wherein:
the semiconductor substrate has a top surface;
the first and second circuits each includes a first doped region extending below the corresponding circuit terminal and having a dopant depth below the top surface;
the STI has a STI depth equal to or greater than the dopant depth.

3. The semiconductor device of claim 2, wherein:
an LDT floor is implanted with an implant;
a portion of the semiconductor substrate directly under a thalweg of the STI is undoped and matches portions of the semiconductor substrate directly under the fin portion and the first doped region.

4. The semiconductor device of claim 3, wherein:
the STI includes sloped walls that extend below the top surface and toward each other to form a concave shape with the thalweg corresponding to the lowest point in the concave shape, wherein the sloped walls are separated by a trench opening width at a height matching the top surface; and
the portion of the semiconductor substrate directly under the thalweg remains undoped based on the sloped walls, the trench opening width, the STI depth, or a combination thereof.

5. The semiconductor device of claim 4, wherein:
the sloped walls form an angle between 91 to 95 degrees with the top surface;
the trench opening width is 30 nm or greater; and
the STI depth is 1 um or less.

6. The semiconductor device of claim 2, wherein:
the LDT has a deep trench depth; and
the STI depth is equal to or less than the deep trench depth.

7. The semiconductor device of claim 2, wherein the fin portion and the first doped region have matching dopant polarity.

8. The semiconductor device of claim 7, wherein:
the fin portion and the first doped region are N-doped regions separated by the shallow trench isolation; and
the first and second circuits each includes an N+ doped region directly below the corresponding circuit terminal, wherein the N+ doped region is shallower and narrower than the first doped region.

9. The semiconductor device of claim 2, wherein the fin portion extends laterally and is connected to the first doped region of the first circuit.

10. The semiconductor device of claim 9, wherein the fin portion is connected to the first doped region between a drain of the first circuit and the gate.

11. The semiconductor device of claim 1, further comprising:
guard structures extending parallel to each other and an arrangement of the first and second circuits with first and second circuits between the guard structures, wherein the fin portion extends laterally and connects with the guard structures to form corresponding junctions.

12. The semiconductor device of claim 11, wherein the junctions between the fin portion and the guard structures each form a p-n diode based on doping states of the fin portion and the guard structures.

13. The semiconductor device of claim 1, wherein at least the first circuit is a high voltage circuit configured to operate using 10V or higher.

14. A method of manufacturing a semiconductor device, the method comprising:
providing a semiconductor substrate;
forming a doped region based on depositing a dopant into a corresponding portion of the semiconductor substrate;
first etching at least a first location and a second location on the semiconductor substrate, to initially form a local deep trench (LDT) at the first location and a shallow trench isolation (STI) at the second location,
wherein the second location is within the doped region and the STI separates the doped region into a fin portion and a first doped region, the STI having an initial depth after the first etching,
wherein the fin portion and the STI are located between the first doped region and the LDT along a lateral direction;
depositing a first implant onto the semiconductor substrate, wherein the first implant is deposited into the LDT and the STI;
after depositing the first implant, second etching at least the STI to a final depth that is greater than the initial depth, wherein second etching includes removing the first implant from within the STI;
forming a liner over portions of the substrate including the deepened STI, wherein the liner covers a thalweg of the STI;
depositing a second implant onto the semiconductor substrate including the STI and the LDT, wherein the liner over the thalweg of the STI prevents the second implant from entering into a portion of the substrate under the thalweg; and
removing the liner to expose the STI.

15. The method of claim 14, wherein:
forming the doped region includes depositing the dopant to a dopant depth;
the final depth of the STI is greater than the dopant depth, wherein the STI extends past and below bottom portions of the fin portion and the first doped region.

16. The method of claim 15, wherein the second etching includes etching the first location to further deepen the LDT to the final depth.

17. The method of claim 15, further comprising:
finalizing the LDT to have a deep trench depth, wherein deep trench depth is greater than the final depth.

18. The method of claim 14, wherein:
the STI corresponds to a first STI;
the fin portion is a first fin portion; and
the first etching includes etching at least a third location within the doped region, adjacent to the second location, and opposite the first location, wherein the third location includes initially forming a second STI and further separating the doped region to form a second fin portion between the first fin portion and the first doped region.

19. The method of claim 18, wherein the second STI has a finalized depth that is different from the final depth of the first STI.

20. The method of claim 14, wherein the first etching includes forming the fin portion connected to the first doped region, a guard portion, or a combination thereof.
